(19) United States
(12) Patent Application Publication
(10) Pub. No.: US 2024/0026518 A1
(43) Pub. Date: Jan. 25, 2024

(54) APPARATUS AND METHOD FOR MANUFACTURING DISPLAY DEVICE

(71) Applicant: Samsung Display Co., Ltd., Yongin-si (KR)

(72) Inventors: Dongwook Kim, Yongin-si (KR); Kwangho Park, Yongin-si (KR); Eugene Kang, Yongin-si (KR); Younghun Park, Yongin-si (KR); Seungjoo Baek, Yongin-si (KR); Dongyun Shin, Yongin-si (KR); Hyunwoo Jang, Yongin-si (KR); Jonghyun Jung, Yongin-si (KR)

(73) Assignee: Samsung Display Co., Ltd., Yongin-si (KR)

(21) Appl. No.: 18/296,490

(22) Filed: Apr. 6, 2023

(30) Foreign Application Priority Data
Jul. 20, 2022 (KR) 10-2022-0089881

(51) Int. Cl. C23C 14/04; H10K 71/16

(52) U.S. Cl. CPC C23C 14/042; H10K 71/166

(57) ABSTRACT

An apparatus for manufacturing a display device includes a mask assembly, and a deposition source including a deposition part that supplies deposition material to the mask assembly. The deposition part includes a deposition frame including an inner space, a crucible disposed in the inner space of the deposition frame to be withdrawn from the deposition frame and accommodating the deposition material, a nozzle connected to the crucible and that sprays the deposition material accommodated in the crucible, a first heating portion disposed in the inner space of the deposition frame and that heats the deposition material accommodated in the crucible, and a second heating portion being movable between a first position at which the nozzle is heated and a second position at which a withdrawal space so that the crucible is withdrawn from the deposition frame.

### CROSS-REFERENCE TO RELATED APPLICATION(S)

This application claims priority to and benefits of Korean Patent Application No. 10-2022-0089881 under 35 U.S.C. § 119, filed on Jul. 20, 2022 in the Korean Intellectual Property Office (KIPO), the entire contents of which are incorporated herein by reference.

### BACKGROUND

### 1. Technical Field

One or more embodiments relate to an apparatus and method for manufacturing a display device.

### 2. Description of the Related Art

Recently, electronic devices are widely used. Various electronic devices, such as mobile electronic devices and stationary electronic devices, are used. These electronic devices include a display device capable of providing visual information, such as an image or video, to a user to support various functions.

The display device displays data visually and may be formed by depositing various layers, such as an organic layer, a metal layer, and the like. A deposition material can be deposited to form multiple layers of the display device. For example, the deposition material may be sprayed from a deposition source and may be deposited on a substrate through a mask assembly. In case that interference between a mask sheet and a shielding stick occurs, the quality of deposition may be lowered because the deposition material may not be deposited at a required position on the substrate.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments include an apparatus and method for manufacturing a display device, whereby a heating portion for heating a nozzle may be moved so that a crucible for accommodating deposition materials may be readily discharged to the outside of a deposition part.

However, this aspect is merely an example, and the scope of the disclosure is not limited thereto.

Additional aspects will be set forth in part in the description which follows and, in part, will be apparent from the description, or may be learned by practice of the presented embodiments of the disclosure.

According to one or more embodiments, an apparatus for manufacturing a display device, may include a mask assembly, and a deposition source including a deposition part that supplies deposition material to the mask assembly. The deposition part may include a deposition frame including an inner space, a crucible disposed in the inner space of the deposition frame to be withdrawn from the deposition frame and accommodating a deposition material, a nozzle connected to the crucible and that sprays the deposition material accommodated in the crucible, a first heating portion disposed in the inner space of the deposition frame and that heats the deposition material accommodated in the crucible, and a second heating portion movable between a first position at which the nozzle is heated and a second position at which a withdrawal space is provided so that the crucible is withdrawn from the deposition frame.

The second heating portion may be connected to the first heating portion to be rotated with respect to the first heating portion between the first position and the second position.

The second heating portion may be connected to the first heating portion to be rotated with respect to the first heating portion between the first position and the second position.

The apparatus may further include a reflector connected to the deposition frame and disposed between the first heating portion and the mask assembly to prevent heat generated in the inner space of the deposition frame from being transferred to the mask assembly.

The reflector may be detachable from the deposition frame.

The second heating portion may be connected to the reflector.

The apparatus may further include an angle limiting portion connected to the deposition frame and that blocks a portion of the deposition material sprayed from the nozzle to limit a supply angle of the deposition material supplied to the mask assembly.

The angle limiting portion may be detachable from the deposition frame.

The second heating portion may limit the supply angle of the deposition material supplied to the mask assembly.

The second heating portion may be connected to the first heating portion to heat the nozzle by heat transferred from the first heating portion.

The second heating portion may include a heating member that generates heat.

According to one or more embodiments, a method of manufacturing a display device may include arranging a mask assembly and a deposition source including a deposition part, and supplying deposition material to the mask assembly by using the deposition source. The deposition part may include a deposition frame including an inner space, a crucible disposed in the inner space of the deposition frame to be withdrawn from the deposition frame and accommodating the deposition material, a nozzle connected to the crucible and that sprays the deposition material accommodated in the crucible, a first heating portion disposed in the inner space of the deposition frame and that heats the deposition material accommodated in the crucible, and a second heating portion movable between a first position at which the nozzle is heated and a second position at which a withdrawal space is provided so that the crucible is withdrawn from the deposition frame.

The deposition part may include a first deposition part and a second deposition part.

The first deposition part may supply a first deposition material, and the second deposition part may supply a second deposition material that is different from the first deposition material.

The first deposition material may include a host component, and the second deposition material may include a dopant component.

The second heating portion may be connected to the first heating portion to be rotated with respect to the first heating portion between the first position and the second position.

The second heating portion may be connected to the first heating portion to be rotated with respect to the first heating portion between the first position and the second position.

The deposition part may further include a reflector connected to the deposition frame and disposed between the first heating portion and the mask assembly to prevent heat generated in the inner space of the deposition frame from being transferred to the mask assembly.

The deposition part may further include an angle limiting portion connected to the deposition frame and that blocks a portion of the deposition material sprayed from the nozzle to limit a supply angle of the deposition material supplied to the mask assembly.

The second heating portion may be connected to the first heating portion to heat the nozzle by heat transferred from the first heating portion.

Other aspects, features, and advantages than those described above may be apparent from the following drawings, the claims, and the detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view illustrating an apparatus for manufacturing a display device according to an embodiment;

FIG. 2 is a schematic perspective view of a deposition source according to an embodiment;

FIG. 3 is a schematic cross-sectional view of the deposition source according to an embodiment, taken along line I-I′ of FIG. 2;

FIGS. 4A and 4B are enlarged schematic views of a deposition source according to an embodiment, which corresponds to portion A of FIG. 3;

FIGS. 5A and 5B are enlarged schematic views of a deposition source according to another embodiment, which corresponds to portion A of FIG. 3;

FIGS. 6A and 6B are enlarged schematic views of a deposition source according to another embodiment, which corresponds to portion A of FIG. 3;

FIG. 7A is an enlarged schematic view of a deposition source according to another embodiment, which corresponds to portion A of FIG. 3;

FIG. 7B is a schematic plan view of a portion of a deposition module according to another embodiment;

FIG. 7C is an enlarged schematic view of a deposition source according to another embodiment, which corresponds to portion A of FIG. 3;

FIG. 7D is a schematic plan view of a portion of a deposition module according to another embodiment;

FIG. 8 is a plan view schematically illustrating a display device manufactured by a method of manufacturing a display device according to an embodiment;

FIG. 9 is a cross-sectional view schematically illustrating a display device manufactured by a method of manufacturing a display device according to an embodiment;

FIG. 10 is an equivalent circuit diagram of pixels according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean any combination including “A, B, or A and B.”

Since various modifications and various embodiments of the disclosure are possible, only a few specific embodiments are illustrated in the drawings and described in detail in the detailed description. Effects and features of the disclosure, and a method of achieving them will be apparent with reference to embodiments described below in detail in conjunction with the drawings. However, the disclosure is not limited to the embodiments disclosed herein, but may be implemented in a variety of forms.

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

As used herein, the singular forms, “a,” “an,” and “the” are intended to include the plural forms as well, unless the context clearly indicates otherwise.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

When a portion such as a layer, a region, a component or the like is on other portions, this is not only when the portion is on other components, but also when other components are interposed therebetween.

In the drawings, for convenience of explanation, the sizes of components may be exaggerated or reduced. For example, since the size and thickness of each component shown in the drawings may be arbitrarily indicated for convenience of explanation, the disclosure is not necessarily limited to the illustration.

In the following embodiment, the x-axis, y-axis, and z-axis, and the u-axis, v-axis, and w-axes are not limited to three axes on an orthogonal coordinate system, and may be interpreted in a broad sense. For example, the x-axis, the y-axis, and the z-axis, and the u-axis, v-axis, and w-axes may be orthogonal to each other, but may refer to different directions that may not be orthogonal to each other.

Embodiments may be implemented in an order other than that described in the specification the specification. For example, a specific process order may be performed differently from the order described. For example, two processes described in succession may be substantially performed at the same time, or in an opposite order to an order to be described.

It will be understood that the terms “connected to” or “coupled to” may include a physical, fluid, and/or electrical connection or coupling.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

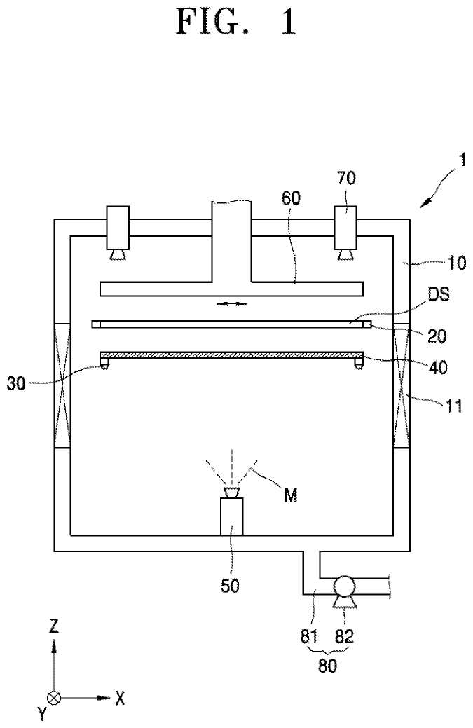

FIG. 1 is a schematic cross-sectional view illustrating an apparatus for manufacturing a display device according to an embodiment.

An apparatus 1 for manufacturing a display device may include a chamber 10, a first support portion 20, a second support portion 30, a mask assembly 40, a deposition source 50, a magnetic force portion 60, a vision portion 70, and a pressure controlling portion 80.

A space may be formed in the chamber 10, and a display substrate DS and the mask assembly 40 may be accommodated in the chamber 10. A portion of the chamber 10 may be open, and a gate valve 11 may be installed in the open portion of the chamber 10. The open portion of the chamber 10 may be open or closed depending on whether the gate valve 11 operates or not.

The display substrate DS may refer to a display substrate DS on which at least one layer of an organic layer, an inorganic layer and a metal layer is deposited on a substrate 100 to be described below and the display device is being manufactured. In other embodiments, the display substrate DS may be a substrate 100 onto which at least one layer of the organic layer, the inorganic layer and the metal layer is not deposited.

The first support portion 20 may support the display substrate DS. The first support portion 20 may have a shape of a plate fixed to the inside of the chamber 10. In another embodiment, the first support portion 20 may have a shape of a shuttle on which the display substrate DS is seated and a linear motion may be performed inside the chamber 10. In another embodiment, the first support portion 20 may include an electrostatic chuck or adhesive chuck disposed in the chamber 10 to be fixed to the chamber 10 or to be moved inside the chamber 10.

The second support portion 30 may support the mask assembly 40. The second support portion 30 may be disposed inside the chamber 10. The second support portion 30 may perform fine adjustment of the position of the mask assembly 40. The second support portion 30 may include a separate driving unit or alignment unit to move the mask assembly 40 in a different direction.

In another embodiment, the second support portion 30 may have a shape of a shuttle. The mask assembly 40 may be seated on the second support portion 30, and the second support portion 30 may transport the mask assembly 40. For example, the second support portion 30 may move to the outside of the chamber 10 and may enter the inside of the chamber 10 from the outside of the chamber 10 after the mask assembly 40 is seated on the second support portion 30.

In the above case, the first support portion 20 and the second support portion 30 may be integrally formed. The first support portion 20 and the second support portion 30 may include a movable shuttle. The first support portion 20 and the second support portion 30 may include a structure for fixing the mask assembly 40 and the display substrate DS in a state in which the display substrate DS is seated on the mask assembly 40, and the display substrate DS and the mask assembly 40 may be linearly moved simultaneously.

However, hereinafter, for convenience of explanation, a shape in which the first support portion 20 and the second support portion 30 are formed to be distinguished from each other and are arranged in different positions, and a shape in which the first support portion 20 and the second support portion 30 are disposed inside the chamber 10, will be described in detail.

The mask assembly 40 may be disposed inside the chamber 10 to face the display substrate DS. A deposition material M may pass through the mask assembly 40 and may be deposited on the display substrate DS.

The deposition source 50 may be disposed to face the mask assembly 40, and the deposition material M may pass through a deposition area EA of the mask assembly 40 and may be supplied to be deposited on the display substrate DS. The deposition source 50 may vaporize or sublimate the deposition material M by heating the deposition material M. The deposition source 50 may be arranged to be fixed inside the chamber 10 or may also be arranged inside the chamber 10 to make a linear motion in a direction.

The magnetic force portion 60 may be disposed inside the chamber 10 to face the display substrate DS and/or the mask assembly 40. The magnetic force portion 60 may apply a magnetic force to the mask assembly 40 to pressurize the mask assembly 40 toward the display substrate DS. In particular, the magnetic force portion 60 may prevent sagging of the mask assembly 40 and may allow the mask assembly 40 to be adjacent to the display substrate DS. The magnetic force portion 60 may maintain a uniform distance between the mask assembly 40 and the display substrate DS.

The vision portion 70 may be disposed in the chamber 10 and may photograph the positions of the display substrate DS and the mask assembly 40. The vision portion 70 may include a camera for photographing the display substrate DS and the mask assembly 40. The positions of the display substrate DS and the mask assembly 40 may be identified based on an image captured by the vision portion 70, and may assist in checking for deformation of the mask assembly 40. Also, the first support portion 20 may adjust the position of the display substrate DS finely based on the image, or the second support portion 30 may adjust the position of the mask assembly 40 finely. However, hereinafter, a case where the second support portion 30 adjusts the position of the mask assembly 40 finely to align the positions of the display substrate DS and the mask assembly 40, will be described in detail.

The pressure controlling portion 80 may be connected to the chamber 10 and may control pressure inside the chamber 10. For example, the pressure controlling portion 80 may control pressure inside the chamber 10 to be equal to or similar to an atmospheric pressure. For example, the pressure controlling portion 80 may control pressure inside the chamber 10 to be equal to or similar to a vacuum state.

The pressure controlling portion 80 may include a connection pipe 81 connected to the chamber 10, and a pump 82 installed on the connection pipe 81. Depending on whether the pump 82 operates or not, outside air may flow into the chamber 10 through the connection pipe 81, or gas inside the chamber 10 may be guided to the outside through the connection pipe 81.

In a method of manufacturing a display device (not shown) by using the apparatus 1 for manufacturing a display device described above, first, the display substrate DS may be prepared.

The pressure controlling portion 80 may maintain the inside of the chamber 10 to be equal to or similar to the atmospheric pressure, and the gate valve 11 may operate so that the open portion of the chamber 10 may be open.

Thereafter, the display substrate DS may be loaded to the inside from the outside of the chamber 10. The display substrate DS may be loaded to the chamber 10 in various ways. For example, the display substrate DS may be loaded from the outside of the chamber 10 to the inside of the chamber 10 through a robot arm disposed outside the chamber 10. In another embodiment, in case that the first support portion 20 is formed in a shuttle shape, the first support portion 20 may be carried out from the inside of the chamber 10 to the outside of the chamber 10, and the display substrate DS may be seated on the first support portion 20 through a separate robot arm disposed outside the chamber 10.

The mask assembly 40 may be disposed inside the chamber 10, as described above. In another embodiment, the mask assembly 40 may be loaded to the inside of the chamber 10 from the outside of the chamber 10 in the same or similar way as that of the display substrate DS.

In case that the display substrate DS is loaded to the inside of the chamber 10, the display substrate DS may be seated on the first support portion 20. The vision portion 70 may photograph the positions of the display substrate DS and the mask assembly 40. The positions of the display substrate DS and the mask assembly 40 may be identified based on the image captured by the vision portion 70. The apparatus 10 for manufacturing a display device may include a separate controller (not shown) to identify the positions of the display substrate DS and the mask assembly 40.

In case that identification of the positions of the display substrate DS and the mask assembly 40 is completed, the second support portion 30 may adjust the position of the mask assembly 40 finely.

Subsequently, the deposition source 50 may operate to supply the deposition material M to the mask assembly 40, and the deposition material M that has passed through multiple pattern holes of the mask assembly 40 may be deposited on the display substrate DS. The deposition source 50 may be moved in parallel to the display substrate DS and the mask assembly 40, or the display substrate DS and the mask assembly 40 may be moved in parallel to the deposition source 50. For example, the deposition source 50 may be moved relative to the display substrate DS and the mask assembly 40. The pump 82 may absorb gas inside the chamber 10 to discharge the inhaled gas to the outside so that pressure inside the chamber 10 may be maintained in the same or similar form as vacuum.

The deposition material M supplied by the deposition source 50 described above may pass through the mask assembly 40 and may be deposited on the display substrate DS. Thus, at least one of multiple layers, for example, an organic layer, an inorganic layer, and a metal layer stacked on a display device to be described later may be formed.

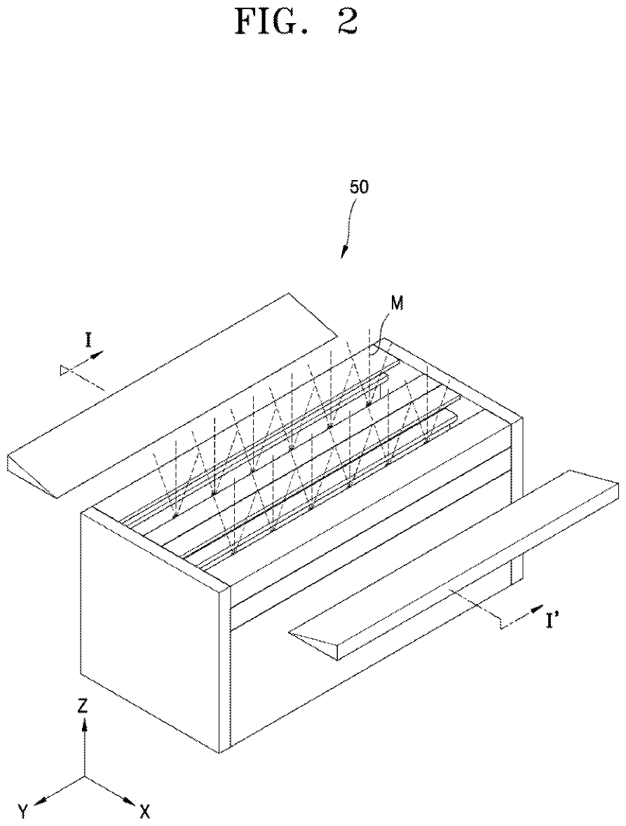

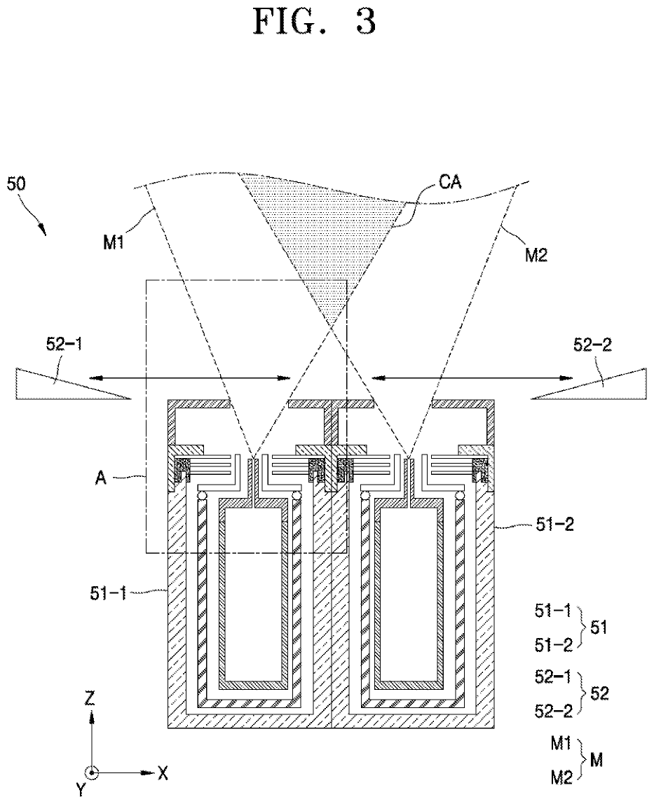

FIG. 2 is a schematic perspective view of a deposition source according to an example, and FIG. 3 is a schematic cross-sectional view of a deposition source according to an embodiment, taken along portion I-I′ of FIG. 2.

Referring to FIGS. 1 through 3, a deposition source 50 according to an embodiment may include a deposition module (part) 51 and a shutter 52.

The deposition module 51 may supply the deposition material M so that the deposition material M may pass through the mask assembly 40 and may be deposited on the display substrate DS. One or more deposition modules 51 may be provided. For example, the deposition module 51 may include a first deposition module 51-1 for supplying a first deposition material M1 and a second deposition module 51-2 for supplying a second deposition material M2.

The first deposition module 51-1 and the second deposition module 51-2 may be arranged side by side so as to supply the deposition material M toward the display substrate DS. While each of the first deposition material M1 and the second deposition material M2 is supplied, an overlapping area CA in which the first deposition material M1 and the second deposition material M2 overlap each other, may be formed. In the above-described structure, a material in which the first deposition material M1 and the second deposition material M2 are mixed with each other, may be deposited on the display substrate DS.

The first deposition material M1 and the second deposition material M2 may be different from each other. For example, the first deposition material M1 may include a host component. For example, the second deposition material M2 may include a dopant component. As a result, a material in which the host component and the dopant component are mixed with each other, may be deposited on the display substrate DS.

The shutter 52 may block the deposition material M supplied by the deposition module 51 from being deposited on the display substrate DS. The shutter 52 may prevent the deposition material M from reaching the display substrate DS by covering a part of the deposition module 51.

As shown in FIGS. 2 and 3, the deposition material M may be deposited on the display substrate DS in a state where the shutter 52 does not cover the deposition module 51. However, in case that the shutter 52 moves to cover a part of the deposition module 51, the deposition material M may not be deposited on the display substrate DS. In this structure, the thickness of the deposition material M deposited on the display substrate DS may be adjusted by adjusting the time that the shutter 52 blocks the deposition material M.

The shutter 52 may include a first shutter 52-1 and a second shutter 52-2. The first shutter 52-1 may block the first deposition material M1 supplied by the first deposition module 51-1, and the second shutter 52-2 may block the second deposition material M2 supplied by the second deposition module 51-2. The first shutter 52-1 may move in a direction (e.g., a +X axis direction) perpendicular to a direction (e.g., a +Z axis direction) in which the first deposition material M1 is supplied, and the second shutter 52-2 may move in a direction (e.g., a −X axis direction) perpendicular to a direction (e.g., the +Z axis direction) in which the second deposition material M2 is supplied. The first shutter 52-1 and the second shutter 52-2 may move to correspond to each other. For example, in a state where the first shutter 52-1 blocks the first deposition material M1, the second shutter 52-2 may block the second deposition material M2. Also, in a state where the first shutter 52-1 does not block the first deposition material M1, the second shutter 52-2 may not block the second deposition material M2. In this structure, the first deposition material M1 and the second deposition material M2 may be simultaneously deposited on the display substrate DS. The first deposition material M1 and the second deposition material M2 may be simultaneously blocked.

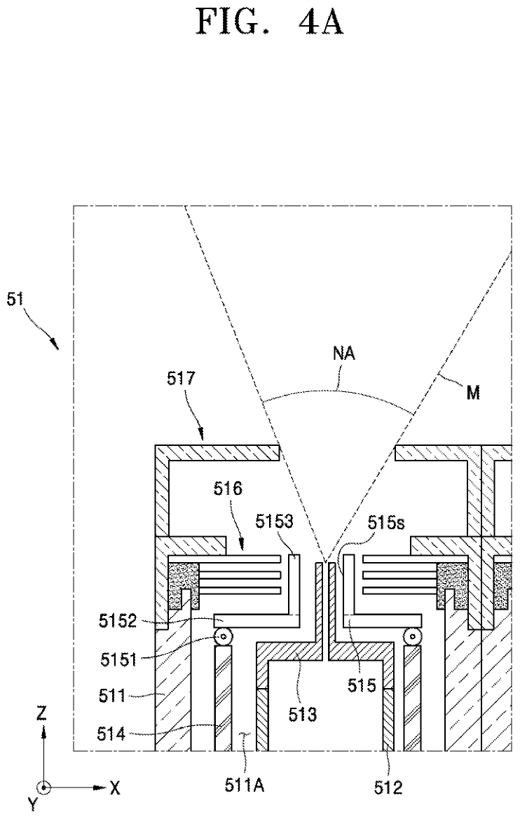

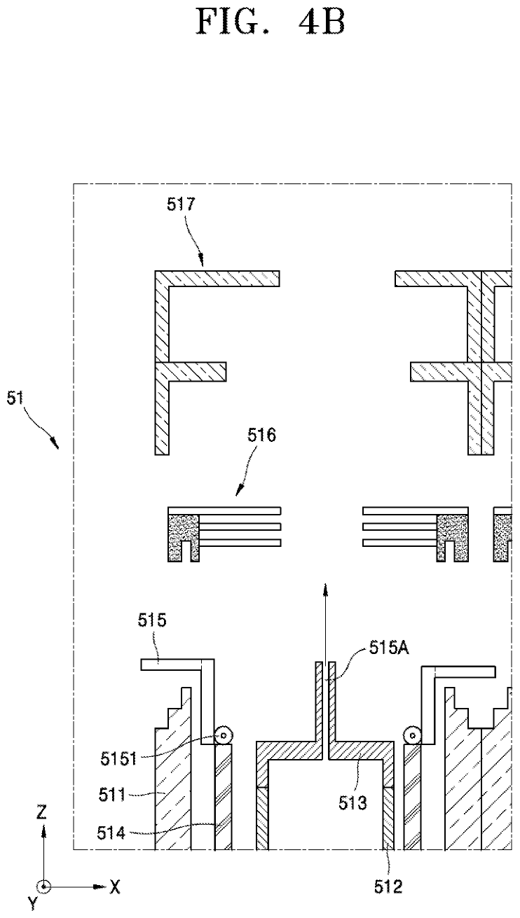

FIGS. 4A and 4B are enlarged schematic views of a deposition source according to an embodiment, which corresponds to portion A of FIG. 3.

Referring to FIGS. 1 through 4A, a deposition module 51 according to an embodiment may include a deposition frame 511, a crucible 512, a nozzle 513, a first heating portion 514, a second heating portion 515, a reflector 516, and an angle limiting portion 517.

The deposition frame 511 may form the appearance of the deposition module 51 to provide an inner space. A side of the deposition frame 511 may be open so that the deposition material M may be sprayed to the outside through the open side of the deposition frame 511. A cooling device may be provided in the deposition frame 511. In this structure, the deposition frame 511 may cool heat generated in the inner space. Thus, the deposition frame 511 may reduce a phenomenon in which heat generated in the inner space is discharged to the outside and affects other components including the mask frame and the substrate. Although the deposition frame 511 is illustrated in a hexahedral shape in which a side thereof is open in FIGS. 2 through 4A, this is only an example, and the shape of the deposition frame 511 is not limited thereto.

The crucible 512 may be disposed in an inner space 511A of the deposition frame 511 to be withdrawn from the deposition frame 511 to accommodate the deposition material M. The nozzle 513 may be connected to the crucible 512 and may spray the deposition material M accommodated in the crucible 512.

The first heating portion 514 may heat the deposition material M accommodated in the crucible 512. As the first heating portion 514 heats the deposition material M, the deposition material M accommodated in the crucible 512 may be vaporized. Thus, the deposition material M vaporized by the first heating portion 514 may be sprayed by the nozzle 513.

The first heating portion 514 may be disposed in the inner space 511A of the deposition frame 511 to be adjacent to the crucible 512. The first heating portion 514 may be disposed to surround the crucible 512. For example, as shown in FIGS. 3 and 4A, the first heating portion 514 may have a cross-sectional shape of ‘⊏”, and the crucible 512 may be accommodated in the first heating portion 514. In this structure, the first heating portion 514 may heat the crucible 512 on a side surface (e.g., a surface in the X-axis direction) and a bottom surface (e.g., a surface in the −Z-axis direction).

The second heating portion 515 may heat the nozzle 513. In this structure, heat may be transferred to the deposition material M passing through the nozzle 513. Accordingly, a phenomenon in which temperature is decreased while the vaporized deposition material M passes through the nozzle 513 and the deposition material M is solidified to block the nozzle 513, may be reduced.

The second heating portion 515 may be disposed in the inner space 511A of the deposition frame 511. The second heating portion 515 may be connected to the first heating portion 514 and may surround the nozzle 513. For example, as illustrated in FIGS. 3 and 4A, two second heating portions 515 are provided, and each of cross-sectional shapes of two second heating portions 515 may include a ‘└’ shape. For example, the second heating portion 515 may include a first heating portion 5152 having an end connected to the first heating portion 514 and having a longitudinal direction (e.g., a X axis direction) perpendicular to a direction (e.g., a +Z axis direction) in which the deposition material M is sprayed, and a second heating portion 5153 that extends in a direction (e.g., an +Z axis direction) in which the deposition material M is sprayed from another end of the first heating portion 5152. In this structure, the deposition material M may be disposed to be adjacent to the nozzle 513.

For example, the second heating portion 515 may include a heating member that generates heat. The heating member may generate heat directly. For example, a heating wire for generating heat may be disposed on a surface 515S facing the nozzle 513 of the second heating portion 515. However, this is only an example, and a method, whereby the second heating portion 515 heats the nozzle 513, is not limited thereto. For example, the second heating portion 515 may not include a separate heating member, and may heat the nozzle 513 by receiving heat from the first heating portion 514.

The reflector 516 may prevent heat generated in the inner space 511A of the deposition frame 511 from being transferred to the mask assembly 40. The reflector 516 may be disposed between the first heating portion 514 and the second heating portion 515, and the mask assembly 40. In such a structure, heat that could be transferred from the first heating portion 514 and the second heating portion 515 to the mask assembly 40 may be blocked by the reflector 516 so as to prevent the mask assembly 40 or the display substrate DS from being damaged by heat. Dissipation of heat generated in the inner space 511A of the deposition frame 511 to the outside may be reduced so that the thermal efficiency of the first heating portion 514 and the second heating portion 515 may be increased.

The reflector 516 may be connected to the deposition frame 511. In case that a cooling device is provided in the deposition frame 511, the deposition frame 511 may cool the reflector 516. In this structure, the reflector 516 may efficiently prevent heat generated in the inner space 511A of the deposition frame 511 from being transferred to the mask assembly 40.

The angle limiting portion 517 may be connected to the deposition frame 511 and may limit a supply angle NA of the deposition material M supplied to the mask assembly 40. A portion of the deposition material M sprayed by the nozzle 513 may be prevented from being supplied to the display substrate DS by the angle limiting portion 517. For example, the angle limiting portion 517 may limit the supply angle NA of the deposition material M by allowing only the deposition material M having the supply angle NA within a specified range to pass.

Referring to FIGS. 1 through 3 and 4B, in the deposition module 51 according to an embodiment, the crucible 512 may be discharged from the inner space 511A of the deposition frame 511.

A state in which the crucible 512 is disposed in the inner space 511A of the deposition frame 511, as shown in FIG. 4A, is referred to as first state, and a state in which the crucible 512 is discharged from the inner space 511A of the deposition frame 511, as shown in FIG. 4B, is referred to as a second state.

In this structure, the deposition module may switch from the first state to the second state in case that the deposition material M contained in the crucible 512 is consumed below a specified range by spraying the deposition material M in the first state by using the nozzle 513. In case that the deposition module is in a second state, a new deposition material M may be supplied to the crucible 512. Thus, in case that the deposition material M accommodated in the crucible 512 is consumed, the new deposition material M may be readily supplied to the crucible 512.

The second heating unit 515 may move to provide a withdrawal space 515A in which the crucible 512 may be discharged from the inner space 511A of the deposition frame 511 in the second state. For example, the second heating portion 515 may move between a first position at which the nozzle 513 is heated, and a second position at which the withdrawal space 515A is provided.

A hinge member 5151 may be disposed on an end of the second heating portion 515. The hinge member 5151 disposed on the end of the second heating portion 515 may be hinge-coupled to the first heating portion 514. In such a structure, the second heating portion 515 may be rotatively movable with respect to the first heating portion 514 between the first position and the second position.

Each of the reflector 516 and the angle limiting portion 517 may be detached from the deposition frame 511. In the first state shown in FIG. 4A, each of the reflector 516 and the angle limiting portion 517 may be mounted on the deposition frame 511. For example, the reflector 516 and the angle limiting unit 517 may be respectively mounted on the deposition frame 511 in a fitting manner. However, this is only an example, and the method where the reflector 516 and the angle limiting portion 517 are mounted on the deposition frame 511, is not limited thereto. In the second state shown in FIG. 4B, each of the reflector 516 and the angle limiting portion 517 may be detached from the deposition frame 511. In this structure, in the second state, the crucible 512 may be more readily discharged from the inner space 511A of the deposition frame 511.

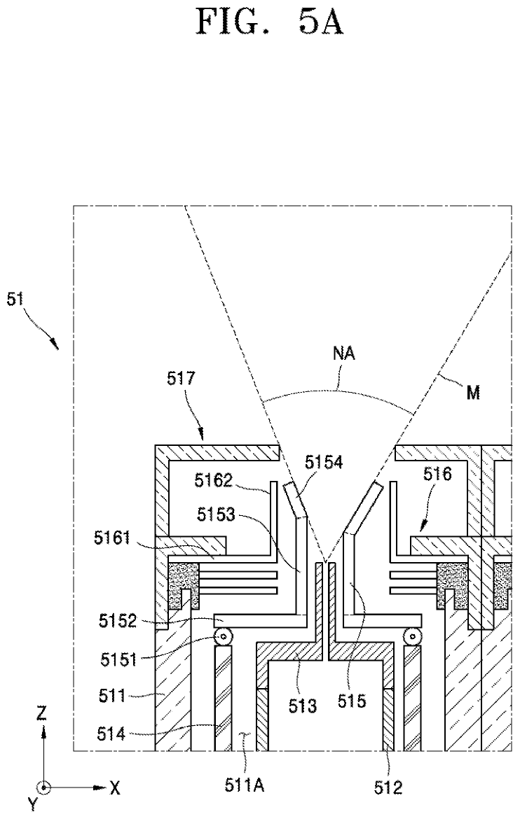

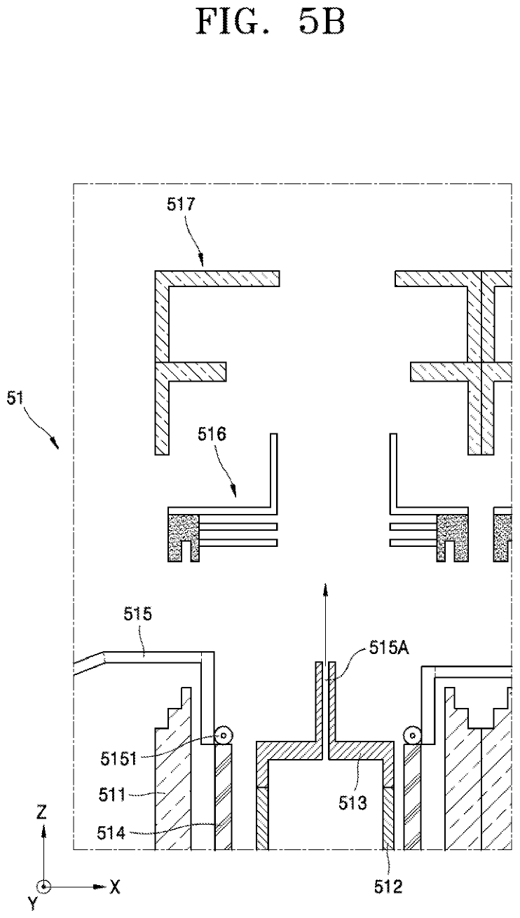

FIGS. 5A and 5B are enlarged schematic views of a deposition source according to another embodiment, which corresponds to portion A of FIG. 3.

Contents substantially the same as those described with reference to FIGS. 1 through 4B will be omitted for convenience of explanation.

Referring to FIGS. 1 through 3 and 5A, in the first state, the second heating portion 515 may limit the supply angle NA of the deposition material M supplied to the mask assembly 40. In such a structure, a phenomenon that the deposition material M sprayed from the nozzle 513 is stacked on the inner surface of the angle limiting portion 517, may be reduced. Thus, the phenomenon that the deposition material M stacked on the inner surface of the angle limiting portion 517 blocks the deposition material M supplied onto the display substrate DS, may be reduced. The second heating portion 515 may further include a third heating portion 5154 in addition to the first heating portion 5152 and the second heating portion 5153 described with reference to FIGS. 1 through 4B.

The third heating portion 5154 may limit the supply angle NA of the deposition material M supplied onto the mask assembly 40. As illustrated in FIG. 5A, based on the cross-sectional shape, the third heating portion 5154 may extend from an end of the second heating portion 5153, and an angle between a pair of third heating portions 5154 may be disposed to correspond to the supply angle NA of the deposition material M sprayed from the nozzle 513.

The reflector 516 may be formed in a shape corresponding to the second heating portion 515. Thus, the reflector 516 may prevent a phenomenon that heat generated from the second heating portion 515 is dissipated to the outside of the deposition frame 511, effectively. For example, in case that the second heating portion 515 includes a first heating portion 5152, a second heating portion 5153 and a third heating portion 5154, the reflector 516 may include a first reflector portion 5161 and a second reflector portion 5162.

The first reflector portion 5161 may be connected to the deposition frame 511, and may have a longitudinal direction (e.g., an X-axis direction) perpendicular to a direction (e.g., a +Z-axis direction) in which the deposition material M is sprayed. Thus, the first reflector portion 5161 may reduce a phenomenon that heat generated in the inner space of the deposition frame 511 is dissipated to an upper portion of the deposition frame 511. The second reflector portion 5162 may extend in a direction (e.g., a +Z axis direction) in which the deposition material M is sprayed from an end of the first reflector portion 5161. As shown in FIG. 5A, based on the cross-sectional shape, the height of the second reflector portion 5161 may correspond to the height of the third heating portion 5154. Thus, the second reflector portion 5162 may reduce a phenomenon that heat generated in the inner space of the deposition frame 511 is dissipated to the side surface (e.g., a surface in an X axis direction) of the deposition frame 511.

Referring to FIGS. 1 through 3 and 5B, in the second state, the crucible 512 may be discharged from the inner space 511A of the deposition frame 511.

The second heating portion 515 may move from the first position to the second position so as to provide a withdrawal space 515A in which the crucible 512 may be discharged from the inner space 511A of the deposition frame 511 in the second state. Each of the reflector 516 and the angle limiting portion 517 may be detached from the deposition frame 511.

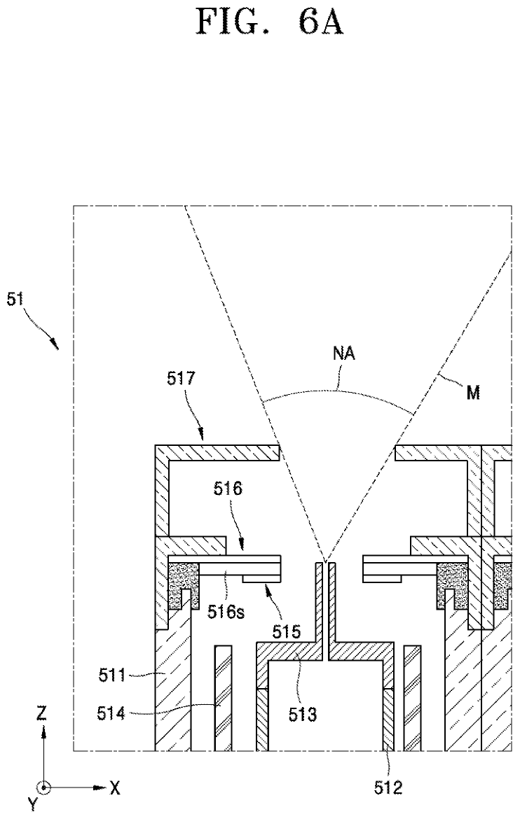

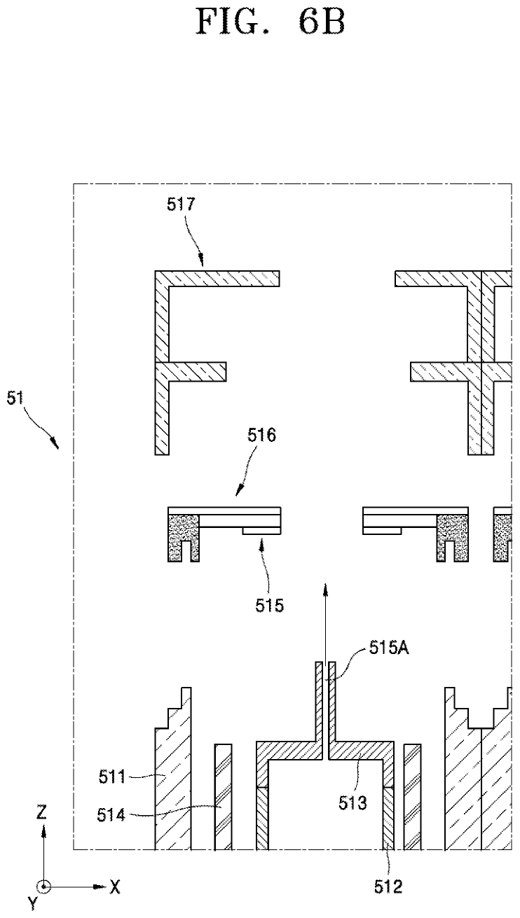

FIGS. 6A and 6B are enlarged schematic views of a deposition source according to another embodiment, which corresponds to portion A of FIG. 3.

Contents substantially the same as those described with reference to FIGS. 1 through 4B will be omitted for convenience of explanation.

Referring to FIGS. 1 through 3 and 6A, the second heating portion 515 may be connected to the reflector 516. For example, in the first state, the second heating portion 515 may be disposed on a surface 516S facing the nozzle 513 of the reflector 516. In such a structure, the second heating unit 515 may be disposed adjacent to the nozzle 513 to heat the nozzle 513. The reflector 516 may reduce a phenomenon in which heat generated in the second heating unit 515 is emitted upward.

Referring to FIGS. 1 through 3 and 6B, in the second state, the crucible 512 may be discharged from the inner space 511A of the deposition frame 511.

In the second state, each of the reflector 516 and the angle limiting portion 517 may be detached from the deposition frame 511. Since the second heating portion 515 is connected to the reflector 516, the reflector 516 is detached from the deposition frame 511 so that the crucible 512 may move from the first position to a second position at which the withdrawal space 515A in which the crucible 512 is discharged from the inner space 511A of the deposition frame 511 is provided.

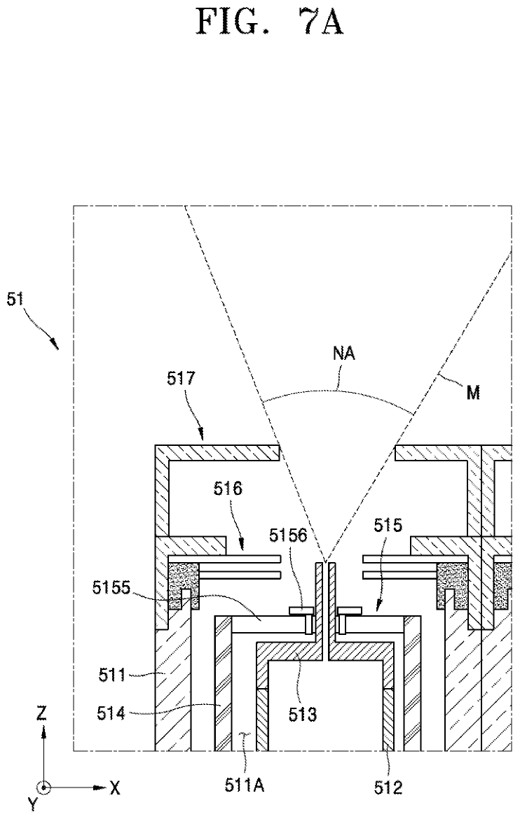

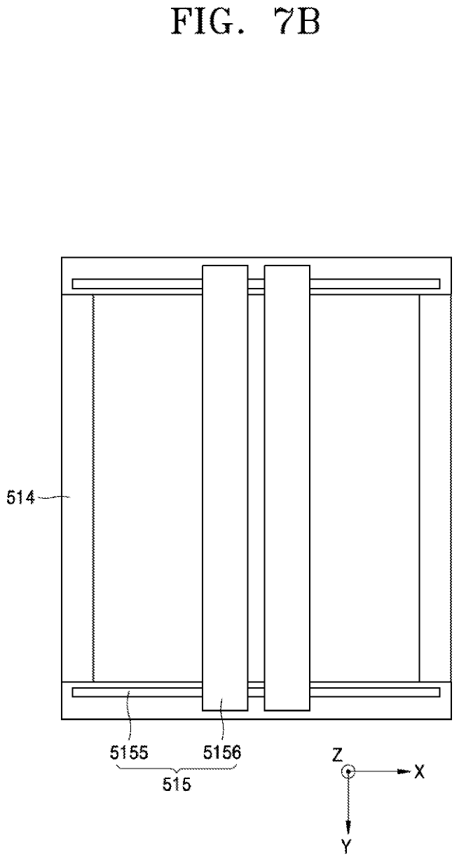

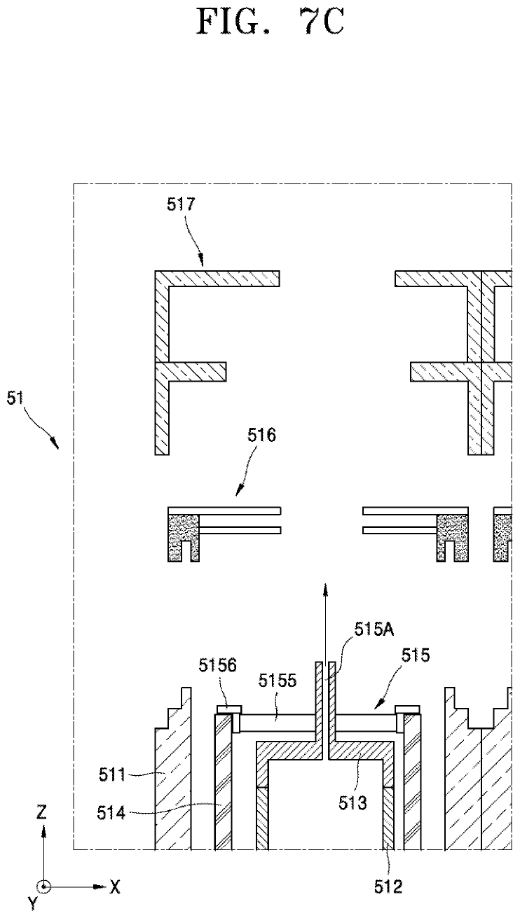

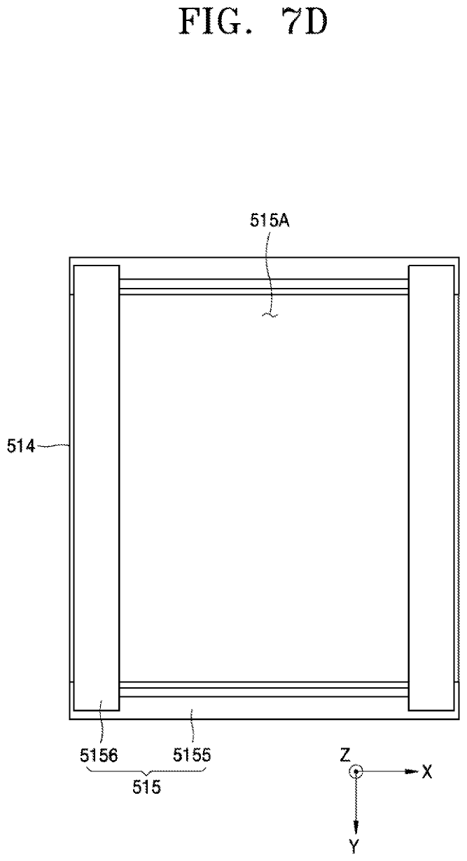

FIG. 7A is an enlarged schematic view of a deposition module according to another embodiment, which corresponds to portion A of FIG. 3, FIG. 7B is a schematic plan view of a portion of the deposition module according to another embodiment, FIG. 7C is an enlarged schematic view of a deposition module according to another embodiment, which corresponds to portion A of FIG. 3, and FIG. 7D is a schematic plan view of a portion of a deposition module according to another embodiment.

Contents substantially the same as those described with reference to FIGS. 1 through 4B will be omitted for convenience of explanation.

Referring to FIGS. 1 through 3 and 7A and 7B, the second heating portion 515 may be connected to the first heating portion 514 so as to be slidable with respect to the first heating portion 514. The second heating portion 515 may include a guide member 5155 and a heating member 5156.

The guide member 5155 may be connected to the first heating portion 514 and may guide the heating member 5156 so as to be slidable with respect to the first heating portion 514. The heating member 5156 may be slidably connected to the guide member 5155. The guide member 5155 and the heating member 5156 may include a material having high thermal conductivity. Thus, heat generated from the first heating portion 514 may be transferred to the heating member 5156 through the guide member 5155. In other embodiments, the heating member 5156 may directly generate heat including the heating member.

Referring to FIGS. 1 through 3 and 7C and 7D, in the second state, the crucible 512 may be discharged from the inner space 511A of the deposition frame 511.

The second heating portion 515 may move from the first position to the second position in the second state. The heating member 5156 may be slidably connected to the guide member 5155. For example, the heating member 5156 may slide in a horizontal direction (e.g., an X-axis direction) based on the cross-sectional shape shown in FIG. 7C. Accordingly, a withdrawal space 515A for allowing the crucible 512 to be discharged from the inner space of the deposition frame 511 may be secured. Each of the reflector 516 and the angle limiting portion 517 may be detached from the deposition frame 511.

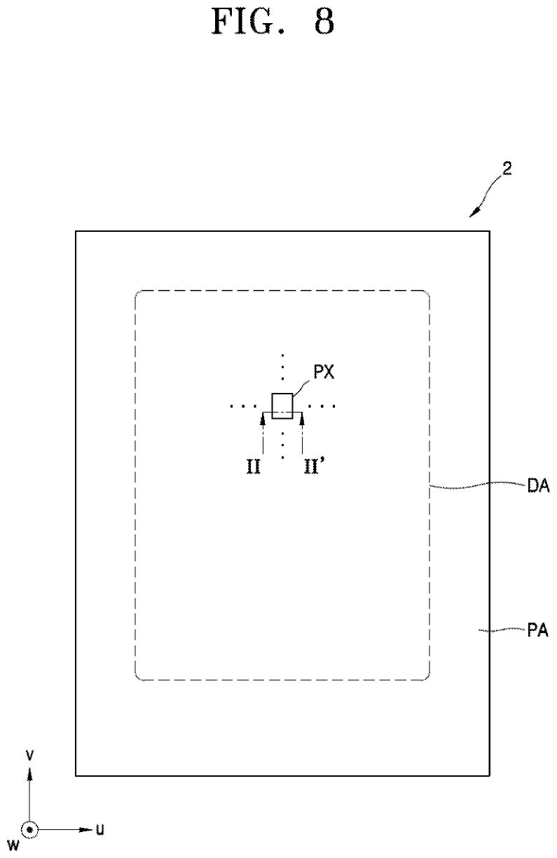

FIG. 8 is a plan view schematically illustrating a display device manufactured by a method of manufacturing a display device according to an embodiment.

Referring to FIG. 8, a display device 2 manufactured according to an embodiment may include a display area DA and a peripheral area PA outside the display area DA. The display device 2 may provide an image to the display area DA through an array of multiple pixels PX arranged in a two-dimensional manner.

The peripheral area PA that is an area in which no image is provided, may surround the display area DA entirely or partially. A driver or the like for providing an electrical signal or power to a pixel circuit corresponding to each of the pixels PX may be disposed in the peripheral area PA. A pad, which is an area in which an electronic device, a printed circuit board, or the like may be electrically connected, may be disposed in the peripheral area PA.

Hereinafter, although the display device 2 includes an organic light emitting diode (OLED) as a light emitting element, the display device 2 of the disclosure is not limited thereto. In another embodiment, the display device 2 may be a light emitting display device including an inorganic light emitting diode, for example, an inorganic light emitting display. The inorganic light emitting diode may include a PN diode including inorganic semiconductor-based materials. In case that a voltage is applied to a PN junction diode in a forward direction, holes and electrons may be injected, and energy generated by recombination of the holes and electrons may be converted into light energy to emit light of a certain color. The inorganic light emitting diode described above may have a width of several to several hundreds of micrometers, and in some embodiments, the inorganic light emitting diode may be referred to as a micro LED. In another embodiment, the display device 2 may be a quantum dot light emitting display.

The display device 2 may be used as a display screen of various products such as portable electronic devices, for example, a mobile phone, a smart phone, a tablet personal computer, a mobile communication terminal, an electronic notebook, an electronic book, a portable multimedia player (PMP), a navigation device, an ultramobile PC (UMPC), and the like, televisions, laptop computers, monitors, billboards, Internet of Things (IOT) devices, and the like. Also, the display device 2 according to an embodiment may be used in a wearable device such as a smart watch, a watch phone, a glasses type display, and a head mounted display (HMD). The display device 2 according to an embodiment may be used as a vehicle instrument panel, a center information display (CID) disposed on a center fascia or a dashboard of a vehicle, a room mirror display that replaces a side mirror of the vehicle, or a display that is disposed on a rear surface of a front seat as an entertainment for a back seat of the vehicle.

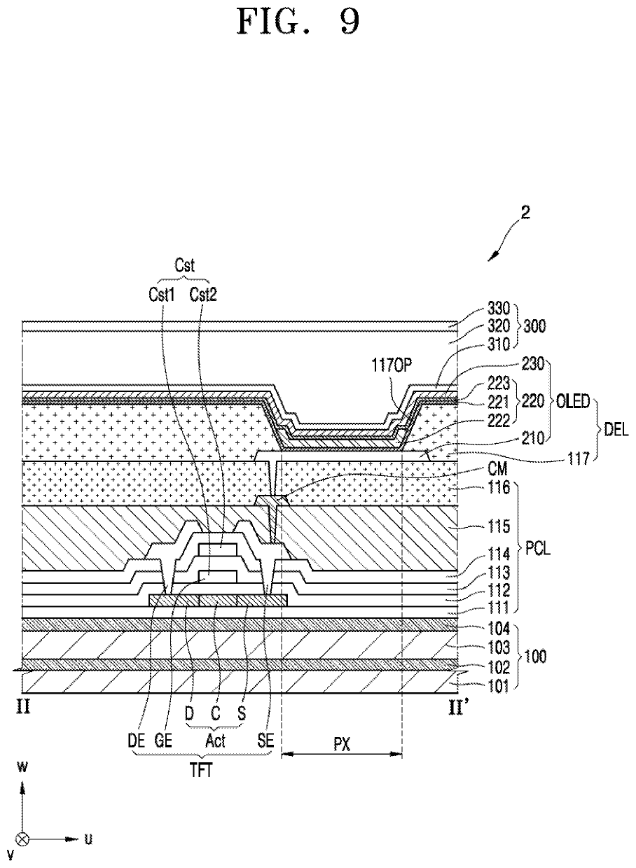

FIG. 9 is a cross-sectional view schematically illustrating a display device manufactured in a method of manufacturing a display device according to an embodiment, which corresponds to the cross-section of the display device taken along line II-II′ of FIG. 8.

Referring to FIG. 9, the display device 2 may include a stacked structure of a substrate 100, a pixel circuit layer PCL, a display element layer DEL, and an encapsulation layer 300. The above-described display substrate (see DS of FIG. 1) may be, for example, a display substrate on which at least one of a pixel circuit layer PCL, a display element layer DEL and an encapsulation layer 300 is stacked on the substrate 100 during a process of manufacturing the display device 2.

The substrate 100 may have a multi-layered structure including a base layer including a polymer resin and an inorganic layer. For example, the substrate 100 may include a base layer including a polymer resin and a barrier layer of an inorganic insulating layer. For example, the substrate 100 may include a first base layer 101, a first barrier layer 102, a second base layer 103, and a second barrier layer 104, which are sequentially stacked on the substrate 100. The first base layer 101 and the second base layer 103 may include polyimide (PI), polyethersulfone (PES), polyarylate, polyetherimide (PEI), polyethylene naphthalate (PEN), polyethylene terephthalate (PET), polyphenylene sulfide (PPS), polycarbonate, cellulose acetate (TAC), cellulose acetate propionate (CAP), and/or the like. The first barrier layer 102 and the second barrier layer 104 may include an inorganic insulating material such as silicon oxide, silicon oxynitride, and/or silicon nitride. The substrate 100 may have flexible characteristics.

A pixel circuit layer PCL may be arranged on the substrate 100. FIG. 9 illustrates that the pixel circuit layer PCL may include a thin film transistor (TFT), a buffer layer 111, a first gate insulating layer 112, a second gate insulating layer 113, an interlayer insulating layer 114, a first planarization insulating layer 115, and a second planarization insulating layer 116, which may be arranged under and/or on components of the TFT.

The buffer layer 111 may reduce or block penetration of foreign substances, moisture, or outside air from a lower portion of the substrate 100, and may provide a flat surface on the substrate 100. The buffer layer 111 may include an inorganic insulating material such as silicon oxide, silicon oxynitride, and/or silicon nitride, and may have a single-layer or multi-layer structure including the above-described material.

The TFT on the buffer layer 111 may include a semiconductor layer Act, and the semiconductor layer Act may include polysilicon. In other embodiments, the semiconductor layer Act may include amorphous silicon, an oxide semiconductor, and/or an organic semiconductor. The semiconductor layer Act may include a channel region C and a drain region D and a source region S, which are disposed on both sides of the channel region C, respectively. The gate electrode GE may overlap the channel region C.

The gate electrode GE may include a low-resistance metal material. The gate electrode GE may include a conductive material such as molybdenum (Mo), aluminum (Al), copper (Cu), titanium (Ti), and/or the like, and may be formed of a multi-layer or single-layer including the material.

The first gate insulating layer 112 between the semiconductor layer Act and the gate electrode GE may include inorganic oxides such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (Zn). The zinc oxide (ZnOₓ) may be zinc oxide (ZnO) and/or zinc peroxide (ZnO₂).

The second gate insulating layer 113 may be provided to cover the gate electrode GE. The second gate insulating layer 113 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and/or zinc oxide (Zn), similarly to the first gate insulating layer 112. The zinc oxide (ZnOₓ) may be zinc oxide (ZnO) and/or zinc peroxide (ZnO₂).

An upper electrode Cst2 of the storage capacitor Cst may be disposed on the second gate insulating layer 113. The upper electrode Cst2 may overlap the gate electrode GE thereunder. The gate electrode GE and the upper electrode Cst2 overlapping the second gate insulating layer 113 with the second gate insulating layer 113 therebetween may form a storage capacitor Cst. For example, the gate electrode GE may function as a lower electrode Cst1 of the storage capacitor Cst.

In this way, the storage capacitor Cst and the thin film transistor TFT may be formed to overlap each other. In some embodiments, the storage capacitor Cst may be formed not to overlap the thin film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be formed of a single layer or a multi-layer of the above-described materials.

The interlayer insulating layer 114 may cover the upper electrode Cst2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnOₓ), and/or the like. The zinc oxide (ZnOₓ) may be zinc oxide (ZnO) and/or zinc peroxide (ZnO₂). The interlayer insulating layer 114 may be a single layer or a multi-layer including the inorganic insulating material described above.

Each of the drain electrode DE and the source electrode SE may be positioned on the interlayer insulating layer 114. The drain electrode DE and the source electrode SE may be connected to the drain region D and the source region S through contact holes formed in insulating layers below them, respectively. The drain electrode DE and the source electrode SE may include a material having good conductivity. The drain electrode DE and the source electrode SE may include a conductive material such as molybdenum (Mo), aluminum (Al), copper (Cu), titanium (Ti), and/or the like, and may be formed of a multi-layer or single-layer including the material. In an embodiment, the drain electrode DE and the source electrode SE may have a multilayer structure of Ti/Al/Ti.

The first planarization insulating layer 115 may cover the drain electrode DE and the source electrode SE. The first planarization insulating layer 115 may include an organic insulating material, such as general-purpose polymer such as polymethylmethacrylate (PMMA) or polystyrene (PS), a polymer derivative with a phenol-based group, an imide-based polymer, an aryl ether-based polymer, an amide-based polymer, a fluorine-based polymer, a p-xylene-based polymer, a vinyl alcohol-based polymer, and a blend thereof.

The second planarization insulating layer 116 may be disposed on the first planarization insulating layer 115. The second planarization insulating layer 116 may include the same material as the first planarization insulating layer 115, and may include an organic insulating material such as a polymer derivative, an acryl-based polymer, an imide-based polymer, an aryl ether-based polymer, an amide-based polymer, a fluorine-based polymer, a p-xylene-based polymer, a vinyl alcohol-based polymer, and a blend thereof.

A display element layer DEL may be disposed on the pixel circuit layer PCL having the above-described structure. The display element layer DEL may include an organic light emitting diode (OLED) as a display element (i.e., a light emitting element), and the OLED may include a stacked structure of a pixel electrode 210, an intermediate layer 220, and a common electrode 230. The OLED may emit, for example, red, green, or blue light, or may emit red, green, blue, or white light. The OLED may emit light through the light emitting area, and the light emitting area may be defined as a pixel PX.

The pixel electrode 210 of the OLED may be electrically connected to the TFT through contact holes formed in the second planarization insulating layer 116 and the first planarization insulating layer 115 and a contact metal CM disposed on the first planarization insulating layer 115.

The pixel electrode 210 may include a conductive oxide such as indium tin oxide (ITO), indium zinc oxide (IZO), zinc oxide (ZnO), indium oxide (In₂O₃), indium gallium oxide (IGO), and/or aluminum zinc oxide (AZO). In another embodiment, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the pixel electrode 210 may further include a layer formed of ITO, IZO, ZnO and/or In₂O₃ on/under the above-described reflective layer.

A pixel defining layer 117 having an opening 117OP exposing a central portion of the pixel electrode 210 may be disposed on the pixel electrode 210. The pixel defining layer 117 may include an organic insulating material and/or an inorganic insulating material. The opening 117OP may define alight emitting area of light emitted from the OLED. For example, the size/width of the opening 117OP may correspond to the size/width of the light emitting area. Accordingly, the size and/or width of the pixel PX may depend on the size and/or width of the opening 117OP of the corresponding pixel defining layer 117.

The intermediate layer 220 may include a light emitting layer 222 formed to correspond to the pixel electrode 210. The light emitting layer 222 may include a polymer or low molecular weight organic material that emits light of a certain color. In other embodiments, the light emitting layer 222 may include an inorganic light emitting material or may include quantum dots.

In an embodiment, the intermediate layer 220 may include a first functional layer 221 and a second functional layer 223 disposed below and above the light emitting layer 222, respectively. The first functional layer 221 may include, for example, a hole transport layer (HTL), or a hole transport layer (HIL) and a hole injection layer (HIL). The second functional layer 223 is a component disposed on the light emitting layer 222 and may include an electron transport layer (ETL) and/or an electron injection layer (EIL). The first functional layer 221 and/or the second functional layer 223 may be a common layer formed to entirely cover the substrate 100, like a common electrode 230 to be described later.

The common electrode 230 may be disposed on the pixel electrode 210 and may overlap the pixel electrode 210. The common electrode 230 may be made of a conductive material having a low work function. For example, the common electrode 230 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In other embodiments, the common electrode 230 may further include a layer such as ITO, IZO, ZnO, and/or In₂O₃ on the (semi)transparent layer including the above-described material. The common electrode 230 may be integrally formed to cover the substrate 100 as a whole.

The encapsulation layer 300 may be disposed on the display element layer DEL and may cover the display element layer DEL. The encapsulation layer 300 may include at least one inorganic encapsulation layer and at least one organic encapsulation layer, and in an embodiment, FIG. 12 illustrates that the encapsulation layer 300 may include a first inorganic encapsulation layer 310, an organic encapsulation layer 320 and a second inorganic encapsulation layer 330, which are sequentially stacked.

The first inorganic encapsulation layer 310 and the second inorganic encapsulation layer 330 may include at least one inorganic material of aluminum oxide, titanium oxide, tantalum oxide, hafnium oxide, zinc oxide, silicon oxide, silicon nitride, and/or silicon oxynitride. The organic encapsulation layer 320 may include a polymer-based material. The polymer-based material may include an acrylic resin, an epoxy resin, polyimide, and/or polyethylene. In an embodiment, the organic encapsulation layer 320 may include acrylate. The organic encapsulation layer 320 may be formed by curing a monomer or applying a polymer. The organic encapsulation layer 320 may have transparency.

Although not illustrated, a touch sensor layer may be disposed on the encapsulation layer 300, and an optical functional layer may be disposed on the touch sensor layer. The touch sensor layer may acquire external input, for example, coordinate information according to a touch event. The optical functional layer may reduce the reflectance of light (external light) incident from the outside toward the display device, and/or improve the color purity of the light emitted from the display device. In an embodiment, the optical functional layer may include a phase retarder and/or a polarizer. The phase retarder may be a film type or a liquid crystal coating type, and may include a λ/2 phase retarder and/or a λ/4 phase retarder. The polarizer may also be a film type or a liquid crystal coating type. The film type may include a stretched synthetic resin film, and the liquid crystal coating type may include liquid crystals arranged in a predetermined or given arrangement. The phase retarder and the polarizer may further include a protective film.

An adhesive member may be disposed between the touch electrode layer and the optical functional layer. The adhesive member may employ general materials without limitation. The adhesive member may be a pressure sensitive adhesive (PSA).

The deposition material M described with reference to FIGS. 1 to 7D may include the intermediate layer 220 described in FIG. 9. For example, the deposition material M may include a light emitting layer 222. For example, the light emitting layer 222 may be a material in which the first deposition material M1 and the second deposition material M2 are mixed.

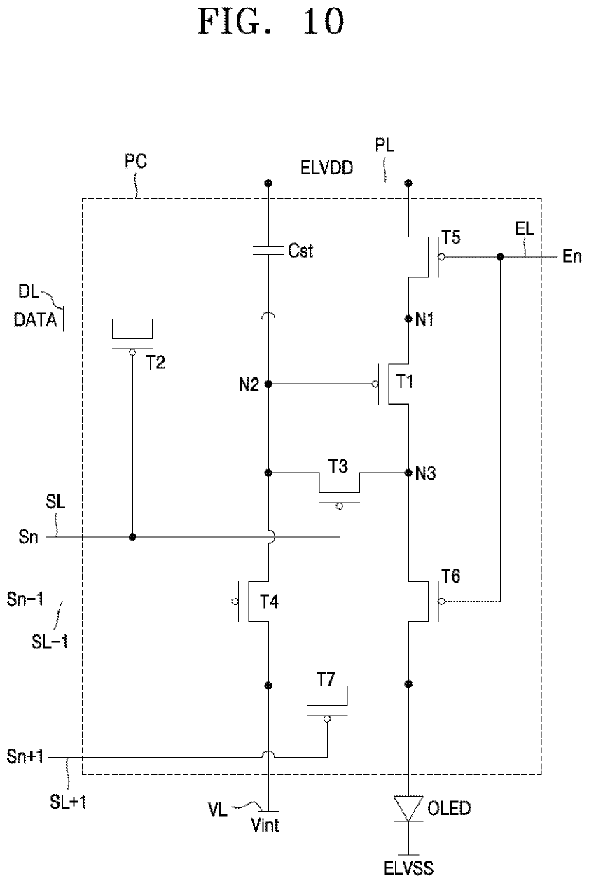

FIG. 10 is an equivalent circuit diagram of pixels according to an embodiment.

Referring to FIG. 10, the pixel circuit PC may include first to seventh transistors T1 to T7, and depending on the type (p-type or n-type) and/or operating conditions of the transistor, a first terminal of each of the first to seventh transistors T1 to T7 may be a source terminal or a drain terminal, and a second terminal of each of the first to seventh transistors T1 to T7 may be a terminal different from the first terminal. For example, in case that the first terminal is a source terminal, the second terminal may be a drain terminal.

The pixel circuit PC may be connected to a first scan line SL for transmitting a first scan signal Sn, a second scan line SL−1 for transmitting a second scan signal Sn−1, a third scan line SL+1 for transmitting a third scan signal Sn+1, a light emitting control line EL for transmitting a light emitting control signal En, a data line DL for transmitting a data signal DATA, a driving voltage line PL for transmitting a driving voltage ELVDD, and an initialization voltage line VL for transmitting an initialization voltage Vint.

The first transistor T1 may include a gate terminal connected to the second node N2, a first terminal connected to the first node N1, and a second terminal connected to the third node N3. The first transistor T1 may serve as a driving transistor, and may receive the data signal DATA according to a switching operation of the second transistor T2 to supply a driving current to the light emitting element. The light emitting element may be an organic light emitting diode (OLED).

The second transistor T2 (switching transistor) may include a gate terminal connected to the first scan line SL, a first terminal connected to the data line DL, and a second terminal connected to a first node N1 (or a first terminal of the first transistor T1). The second transistor T2 may perform a switching operation of transmitting the data signal DATA transmitted to the data line DL to the first node N1 by being turned on according to the first scan signal Sn transmitted through the first scan line SL.

The third transistor T3 (compensation transistor) may include a gate terminal connected to the first scan line SL, a first terminal connected to a second node N2 (or a gate terminal of the first transistor T1), and a second terminal connected to a third node N3 (or a second terminal of the first transistor T1). The third transistor T3 may be turned on according to the first scan signal Sn transmitted through the first scan line SL to connect the first transistor T1 to a diode. The third transistor T3 may have a structure in which two or more transistors are connected in series.

The fourth transistor T4 (first initialization transistor) may include a gate terminal connected to the second scan line SL−1, a first terminal connected to the initialization voltage line VL, and a second terminal connected to the second node N2. The fourth transistor T4 may be turned on according to the second scan signal Sn−1 transmitted through the second scan line SL−1 to transmit the initialization voltage Vint to the gate terminal of the first transistor T1 to initialize the gate voltage of the first transistor T1. The fourth transistor T4 may have a structure in which two or more transistors are connected in series.

The fifth transistor T5 (first light emitting control transistor) may include a gate terminal connected to the light emitting control line EL, a first terminal connected to the driving voltage line PL, and a second terminal connected to the first node N1. The sixth transistor T6 (second light emitting control transistor) may include a gate terminal connected to the light emitting control line EL, a first terminal connected to the third node N3, and a second terminal connected to a pixel electrode of the OLED. The fifth transistor T5 and the sixth transistor T6 may be simultaneously turned on according to the light emitting control signal En transmitted through the light emitting control line EL to allow current to flow through the OLED.

The seventh transistor T7 (second initialization transistor) may include a gate terminal connected to the third scan line SL+1, a second terminal of the sixth transistor T6, a first terminal connected to the pixel electrode of the OLED, and a second terminal connected to the initialization voltage line VL. The seventh transistor T7 may be turned on according to the third scan signal Sn+1 transmitted through the third scan line SL+1 and may transmit the initialization voltage Vint to the pixel electrode of the OLED to initialize a voltage of the pixel electrode of the OLED. The seventh transistor T7 may be omitted.

The capacitor Cst may include a first electrode connected to the second node N2 and a second electrode connected to the driving voltage line PL.

The OLED may include a pixel electrode and a counter electrode facing the pixel electrode, and the counter electrode may receive a common voltage ELVSS. The OLED may receive a driving current from the first transistor T1 and emit light in a certain color to display an image. The counter electrode may be provided in common with multiple pixels, for example, integrally.

As described above, although the disclosure has been described with reference to the embodiments illustrated in the drawings, this is merely an example, and it will be understood that various modifications may be made therefrom by those skilled in the art.

According to embodiments of the disclosure, in case that the deposition material accommodated in the crucible is consumed, the crucible may be readily and simply discharged to the outside of the deposition module, thereby facilitating replacement of the crucible or charging of the deposition material.

The effects of the disclosure are not limited to the above-mentioned effects, and other effects that are not mentioned will be clearly understood by those skilled in the art from the description.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure.

What is claimed is:

1. An apparatus for manufacturing a display device, the apparatus comprising:
a mask assembly; and
a deposition source comprising a deposition part that supplies deposition material to the mask assembly, wherein
the deposition part comprises:
a deposition frame including an inner space;
a crucible disposed in the inner space of the deposition frame to be withdrawn from the deposition frame and accommodating the deposition material;
a nozzle connected to the crucible and that sprays the deposition material accommodated in the crucible;
a first heating portion disposed in the inner space of the deposition frame and that heats the deposition material accommodated in the crucible; and
a second heating portion movable between a first position at which the nozzle is heated and a second position at which a withdrawal space is provided so that the crucible is withdrawn from the deposition frame.

2. The apparatus of claim 1, wherein the second heating portion is connected to the first heating portion to be rotated with respect to the first heating portion between the first position and the second position.

3. The apparatus of claim 1, wherein the second heating portion is connected to the first heating portion to be rotated with respect to the first heating portion between the first position and the second position.

4. The apparatus of claim 1, further comprising:
a reflector connected to the deposition frame and disposed between the first heating portion and the mask assembly to prevent heat generated in the inner space of the deposition frame from being transferred to the mask assembly.

5. The apparatus of claim 4, wherein the reflector is detachable from the deposition frame.

6. The apparatus of claim 4, wherein the second heating portion is connected to the reflector.

7. The apparatus of claim 1, further comprising:
an angle limiting portion connected to the deposition frame and that blocks a portion of the deposition material sprayed from the nozzle to limit a supply angle of the deposition material supplied to the mask assembly.

8. The apparatus of claim 7, wherein the angle limiting portion is detachable from the deposition frame.

9. The apparatus of claim 7, wherein the second heating portion limits a supply angle of the deposition material supplied to the mask assembly.

10. The apparatus of claim 1, wherein the second heating portion is connected to the first heating portion to heat the nozzle by heat transferred from the first heating portion.

11. The apparatus of claim 1, wherein the second heating portion comprises a heating member that generates heat.

12. A method of manufacturing a display device, the method comprising:
arranging a mask assembly and a deposition source including a deposition part; and
supplying a deposition material to the mask assembly by using the deposition source, wherein
the deposition part comprises:
a deposition frame including an inner space;
a crucible disposed in the inner space of the deposition frame to be withdrawn from the deposition frame and accommodating the deposition material;
a nozzle connected to the crucible and that sprays the deposition material accommodated in the crucible;
a first heating portion disposed in the inner space of the deposition frame and that heats the deposition material accommodated in the crucible; and
a second heating portion movable between a first position at which the nozzle is heated and a second position at which a withdrawal space is provided so that the crucible is withdrawn from the deposition frame.

13. The method of claim 12, wherein the deposition part comprises a first deposition part and a second deposition part.

14. The method of claim 13, wherein
the first deposition part supplies a first deposition material, and
the second deposition part supplies a second deposition material different from the first deposition material.

15. The method of claim 14, wherein
the first deposition material comprises a host component, and
the second deposition material comprises a dopant component.

16. The method of claim 12, wherein the second heating portion is connected to the first heating portion to be rotated with respect to the first heating portion between the first position and the second position.

17. The method of claim 12, wherein the second heating portion is connected to the first heating portion to be rotated with respect to the first heating portion between the first position and the second position.

18. The method of claim 12, wherein the deposition part further comprises a reflector connected to the deposition frame and disposed between the first heating portion and the mask assembly to prevent heat generated in the inner space of the deposition frame from being transferred to the mask assembly.

19. The method of claim 12, wherein the deposition part further comprises an angle limiting portion connected to the deposition frame and that blocks a portion of the deposition material sprayed from the nozzle to limit a supply angle of the deposition material supplied to the mask assembly.

20. The method of claim 12, wherein the second heating portion is connected to the first heating portion to heat the nozzle by heat transferred from the first heating portion.
